(19) United States
(12) Patent Application Publication
(10) Pub. No.: US 2016/0189934 A1
(43) Pub. Date: Jun. 30, 2016

(54) PLASMA PROCESSING APPARATUS

(71) Applicant: TOKYO ELECTRON LIMITED, Tokyo (JP)

(72) Inventor: Toshihisa NOZAWA, Miyagi (JP)

(73) Assignee: TOKYO ELECTRON LIMITED, Tokyo (JP)

(21) Appl. No.: 14/971,811

(22) Filed: Dec. 16, 2015

(30) Foreign Application Priority Data
Dec. 24, 2014 (JP) 2014-260000

(51) Int. Cl. H01J 37/32

(52) U.S. Cl. CPC H01J 37/32532; H01J 37/32009; H01J 37/3244

(57) ABSTRACT

Provided is a plasma processing apparatus that processes a substrate by converting a processing gas into plasma. A plurality of rotatable substrate stages are provided at a lower side within a processing container. An upper electrode is provided at an upper side within the processing container. The upper electrode is supplied with a high frequency wave from a high frequency power source to convert a processing gas supplied into the processing container into plasma. The upper electrode is rotatable about a vertical portion of an electrode support member by a driving mechanism and a rotary mechanism.

### CROSS-REFERENCE TO RELATED APPLICATIONS

This application is based on and claims priority from Japanese Patent Application No. 2014-260000 filed on Dec. 24, 2014 with the Japan Patent Office, the disclosure of which is incorporated herein in its entirety by reference.

### TECHNICAL FIELD

The present disclosure relates to a plasma processing apparatus.

### BACKGROUND

In the manufacture of a semiconductor device, a plasma processing is performed to form a film on a substrate in a processing container or to etch an insulation film on the substrate. The plasma processing is performed using a plasma processing apparatus having functions of introducing processing gas into the processing container and converting the processing gas into plasma.

Such a kind of a plasma processing apparatus including a mounting table that places a substrate thereon within a decompressible processing container, and, for example, an upper electrode or a microwave antenna is arranged at a position facing the substrate. A processing gas supplied to the surroundings of the upper electrode or the microwave antenna is converted into plasma, and then a film formation processing or an etching processing is performed on the substrate.

In such a plasma processing apparatus, a so-called batch-type plasma processing apparatus has been recently proposed in order to improve a throughput in which a plurality of substrates are placed within the processing container and the plasma processing are simultaneously performed for the plurality of substrates. See, for example, Japanese Patent Laid-Open Publication No. 2001-140077.

The batch-type plasma processing apparatus are configured such that a size (diameter) of a susceptor—a mounting table also serving as a lower electrode—is enlarged to place a plurality of substrates thereon, and a size (diameter) of an upper electrode facing the susceptor is also correspondingly enlarged to cover the plurality of substrates. It is necessary to perform a uniform processing for each substrate when the plasma processing is simultaneously performed for the plurality of substrates. Thus, the plasma processing apparatus described in Japanese Patent Laid-Open Publication No. 2001-140077 is configured such that a gas is horizontally injected from a plurality of nozzle holes that are formed in the opposite sides of a gas pipe horizontally arranged through a space between the upper electrode and the susceptor.

### SUMMARY

The present disclosure provides the present disclosure provides a plasma processing apparatus that processes a substrate by converting a processing gas into plasma. The plasma processing apparatus includes: a processing container that airtightly accommodates the substrate therein; a plurality of mounting tables provided at a lower side within the processing container, and each configured to place the substrate thereon; and an upper electrode provided at an upper side within the processing container to face the plurality of mounting tables. The upper electrode is configured to be rotatable about a center of the upper electrode as a central axis within the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical sectional view illustrating a schematic configuration of a plasma processing apparatus according to an exemplary embodiment of the present disclosure.

FIG. 2 is a bottom view illustrating an exemplary upper electrode that may be employed in the plasma processing apparatus of FIG. 1, in which the upper electrode includes an electrode body divided into several zones.

FIG. 3 is a bottom view illustrating an exemplary upper electrode that may be employed in the plasma processing apparatus of FIG. 1, in which the upper electrode includes electrode bodies that are concentrically arranged.

FIG. 4 is a bottom view illustrating an exemplary upper electrode that may be employed in the plasma processing apparatus of FIG. 1, in which the upper electrode includes annular electrode bodies.

FIG. 5 is a plan view schematically illustrating an arrangement of a substrate stage in the plasma processing apparatus of FIG. 1.

FIG. 6 is a plan explanatory view schematically illustrating a state in which a retraction space for a conveyance arm is provided in a bottom portion of a processing container.

FIG. 7 is a plan explanatory view schematically illustrating a state in which a recess accommodating a conveyance arm is provided in a bottom portion of a processing container.

FIG. 8 is a plan explanatory view schematically illustrating a state in which the conveyance arm receives a wafer conveyed into the processing container.

FIG. 9 is a plan explanatory view schematically illustrating a state in which a cover is conveyed into the processing container, after a wafer is conveyed onto each substrate stage.

FIG. 10 is a plan explanatory view schematically illustrating a state in which the conveyance arm receives the cover of FIG. 9.

FIG. 11 is a plan explanatory view schematically illustrating a state in which the cover of FIG. 9 is in close contact with the recess.

FIG. 12 is a side sectional explanatory view schematically illustrating a state in which an accommodating portion formed by upper and lower chambers is provided in the processing container.

FIG. 13 is a side sectional explanatory view schematically illustrating a state in which the upper chamber moves down to be in close contact with the lower chamber in FIG. 12.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here

Even if the gas supply is adapted to be uniformly injected, it is impossible to perform a uniform plasma processing for each substrate unless the generated plasma is uniformly and broadly spread over each substrate. For example, in the large-diameter upper electrode that is employed in the conventional plasma processing apparatus, densities and electric potentials of generated plasma vary in respective portions so that it is difficult to achieve a uniform plasma distribution.

Accordingly, the present disclosure has been made in consideration the above-described problems, and is to realize a uniform plasma distribution for a plurality of substrates on a mounting table, thereby realizing the uniformity in processing in a plasma processing apparatus that simultaneously performs is a plasma processing for a plurality of substrates.

In order to accomplish the above object, the present disclosure provides a plasma processing apparatus that processes a substrate by converting a processing gas into plasma. The plasma processing apparatus includes: a processing container that airtightly accommodates the substrate therein; a plurality of mounting tables provided at a lower side within the processing container, and each configured to place the substrate thereon; and an upper electrode provided at an upper side within the processing container to face the plurality of mounting tables. The upper electrode is configured to be rotatable about a center of the upper electrode as a central axis within the processing container.

According to the present disclosure, since the upper electrode provided at the upper position within the processing container to face the plurality of mounting tables is configured to be rotatable about the center of the upper electrode as the central axis, a uniform plasma distribution for a plurality of substrates on the mounting tables may be realized, and consequently a uniform processing may be achieved. Further, the upper electrode mentioned herein includes, for example, an electrode supplied with high-frequency power, various antennas generating plasma by received microwaves, or a dielectric plate.

Each mounting table may be configured to rotatable about a center of the mounting table as a central axis.

The upper electrode may have a plurality of radially zone-divided electrode bodies which are supplied with a high frequency wave.

The upper electrode may have an annular electrode body which is supplied with a high frequency wave.

The upper electrode may have a configuration in which a plurality of annular electrode bodies supplied with a high frequency wave are arranged concentrically. In such a case, the high frequency wave supplied to each electrode body may be individually subjected to an output control.

A conveyance arm may be installed within the processing container to convey the substrate onto each mounting table.

A retraction space may be formed within the processing container to allow the conveyance arm to be retracted without interfering with the mounting tables.

An accommodating portion may be formed within the processing container to airtightly accommodate the conveyance arm therein.

The accommodating portion may include, for example, a recess that accommodates the conveyance arm therein and a cover that airtightly closes the recess, or include a lower chamber and an upper chamber that may come into close contact with the lower chamber and move up and down.

According to the present disclosure, a uniform plasma distribution may be realized for a plurality of substrates on a mounting table, thereby realizing uniformity in processing.

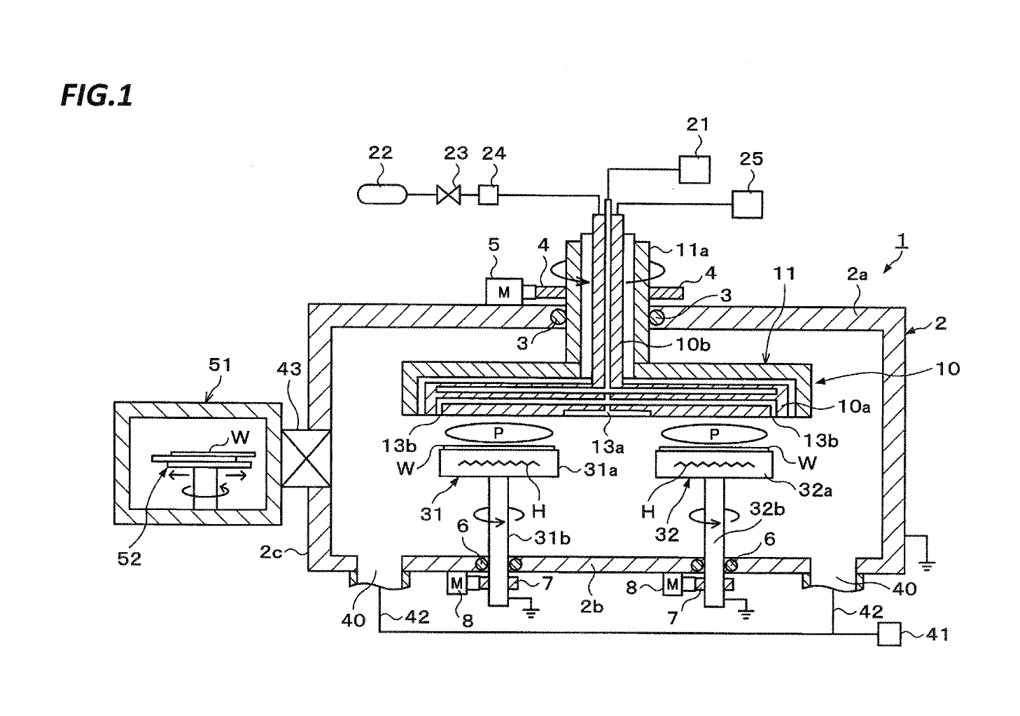

Hereinafter, exemplary embodiments of the present disclosure will be described with reference to the accompanying drawings. FIG. 1 is a vertical sectional view illustrating the schematic configuration of a plasma processing apparatus 1 according to an exemplary embodiment of the present disclosure. Further, the plasma processing apparatus 1 according to the present exemplary embodiment is configured as an apparatus for performing an etching processing on a surface of a wafer W as a substrate. Herein, the same reference numerals are used throughout the different drawings to designate the same or similar components, and duplicated descriptions will be omitted.

The plasma processing apparatus 1 includes an upper electrode 10 at an upper side within the processing container 2 of which the interior is airtightly maintained. The processing container 2 is grounded. The upper electrode 10 includes a disc-shaped electrode body 10a, and a vertical portion 10b extending vertically from the top surface of the electrode body 10a. The upper electrode 10 is supported by an electrode support member 11 that is formed of an insulator in a shape similar to that of the upper electrode 10, and covered by the electrode support member 11 except for the bottom surface thereof. While a cavity is illustrated in the drawing as being formed between the upper electrode 10 and the electrode support member 11 for the convenience of illustration, the upper electrode 10 and the electrode support member 11 are airtightly integrated with each other.

A vertical portion 11a of the electrode support member 11 vertically penetrates a top plate portion 2a of the processing container 2, and a sealant 3 is provided in the penetrating portion. A rotary mechanism 4 is provided on an outer circumference of the vertical portion 11a outside the processing container 2, and the electrode support member 11 rotates about the vertical portion 11a with the aid of the rotary mechanism 4 as the drive mechanism 5 such as, for example, a motor, is operated. Thus, the upper electrode 10 supported by the electrode support member 11 rotates about the vertical portion 10b according to the rotation of the electrode support member 11.

A coolant flow path 12 and a gas flow path 13 are formed within the electrode body 10a and the vertical portion 10b of the upper electrode 10, respectively. A coolant may be supplied from a coolant supply source 21 to the coolant flow path 12. For example, a processing gas required for the plasma etching processing may be supplied from a gas supply source 22 to a gas flow path 13 through a valve 23 and a mass flow controller 24. Further, a predetermined high frequency of, for example, 13.56 MHz may be supplied from a high-frequency power supply 25 to the upper electrode 10 through the vertical portion 10b.

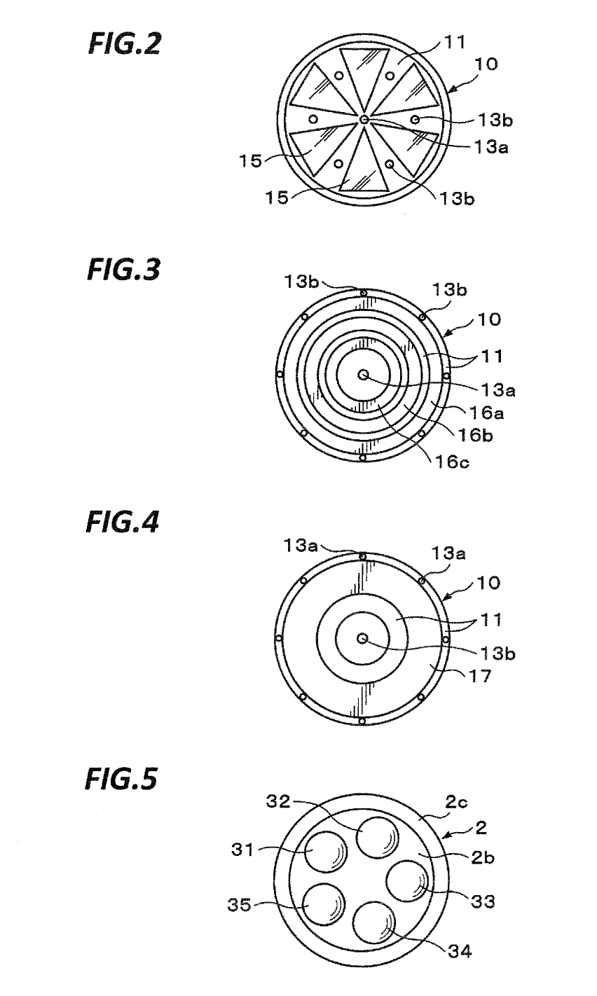

Processing gas supply ports 13a and 13b are formed in a central portion and a peripheral portion of the electrode body 10a so as to supply the processing gas from the gas flow path 13. Further, the electrode body 10a may not have a single disc shape, and electrode bodies having, for example, the shapes of FIGS. 2 to 4 may be proposed. That is, in the upper electrode 10 illustrated in FIG. 2, electrode bodies 15 supplied with the high frequency have a radially zone-divided shape. That is, each electrode body 15 has the shape of an isosceles triangle with the same shape and the same size. A plurality of electrode bodies 15 are disposed on the bottom surface of the electrode support member 11 at predetermined intervals.

The upper electrode 10 illustrated in FIG. 3 includes electrode bodies that are concentrically disposed on the bottom surface of the electrode support member 11 at predetermined intervals. That is, annular electrode bodies 16a, 16b, 16c having different diameters are concentrically arranged. In this case, high frequencies of different outputs may be supplied to the electrode bodies 16a, 16b, 16c, respectively. By supplying the high frequencies of the different outputs to the electrode bodies 16a, 16b, 16c, respectively, the density and intensity of plasma may be more uniformized.

In the upper electrode 10 illustrated in FIG. 4, one annular electrode body 17 is arranged on the bottom surface of the electrode support member 11. As will be described later, this arrangement corresponds to a case where respective substrate stages 31 to 35—mounting tables facing the upper electrode 10—are arranged annularly. By employing such an annular electrode body 17, a ring-shape plasma source is provided to keep the plasma density constant in the circumferential direction of a rotating surface.

The substrate stages serving as the mounting tables (e.g., five substrate stages 31 to 35 in the present exemplary embodiment as illustrated in FIGS. 1 and 5) are arranged annularly on the bottom portion within the processing container 2 at predetermined intervals.

The respective substrate stages 31 to 35 have the same configuration. Referring to the substrate stage 31 as an example, the substrate stage 31 includes a disc-shaped mounting unit 31a on which a wafer W (substrate) is placed and a support member 31b provided at the bottom surface side of the mounting unit 31a. The support member 31b penetrates the bottom portion 2b of the processing container to protrude out from the processing container 2. Further, a sealant 6 is provided in the penetrating portion.

A rotary mechanism 7 is provided on an outer circumference of the support member 31b outside the processing container 2, and the support member 31b rotates about the central axis of the support member 31b with the aid of the rotary mechanism 7, by the operation of the drive mechanism 8 such as, for example, a motor. Thus, the mounting unit 31a supported by the support member 31b rotates about the support member 31b as the support member 31b rotates. For the substrate stage 32, the mounting unit 32a similarly rotates about the support member 32b as the support member 32b rotates. The substrate stage 31 is grounded through the support member 31b. Further, a heater H is installed within the mounting unit of each of the substrate stages 31 to 35, and may regulate the mounted wafer W to a predetermined temperature.

An exhaust port 40 is formed in the bottom portion of the processing container 2. By the operation of the exhaust unit 41, the atmosphere within the processing container 2 is exhausted to the outside of the processing container 2 through an exhaust pipe 42, and the interior of the processing container 2 may be maintained at a predetermined decompression degree.

A load lock chamber 51 is connected to the sidewall 2c of the processing container 2 via a gate valve 43. A conveyance arm 52 is installed within the load lock chamber 51 to rotatably hold the wafer W and to be movable into and out of the processing container 2.

Since the plasma processing apparatus 1 according to the exemplary embodiment is configured as described above and five substrate stages 31 to 35 are provided within the processing container 2 to place a wafer W on each substrate stage, a plasma processing (e.g., etching processing) may be performed on five wafers W at once by generating plasma P on each wafer W.

Further, during the plasma processing, the upper electrode 10 may rotate about the electrode support member 11. Therefore, even if a large-diameter upper electrode 10 covering five wafers W is employed, for example, the density and potential of generated plasma generated may be uniformized on respective portions. Thereby a uniform plasma distribution may be achieved for each wafer W. In addition, in the present exemplary embodiment, since each of the substrate stages 31 to 35 itself is also rotatable, the plasma processing for each wafer W may be further uniformized.

However, when the substrate stages 31 to 35 are annularly arranged in the processing container 2 as shown in FIG. 5, it is necessary to make each of the substrate stages 31 to 35 within the processing container 2 accessible by the conveyance arm 52 in the load lock chamber 51 when each wafer W is delivered to each of the substrate stages 31 to 35. Then, it is expected that the configuration of the conveyance arm 52 will be very complicated and enlarged.

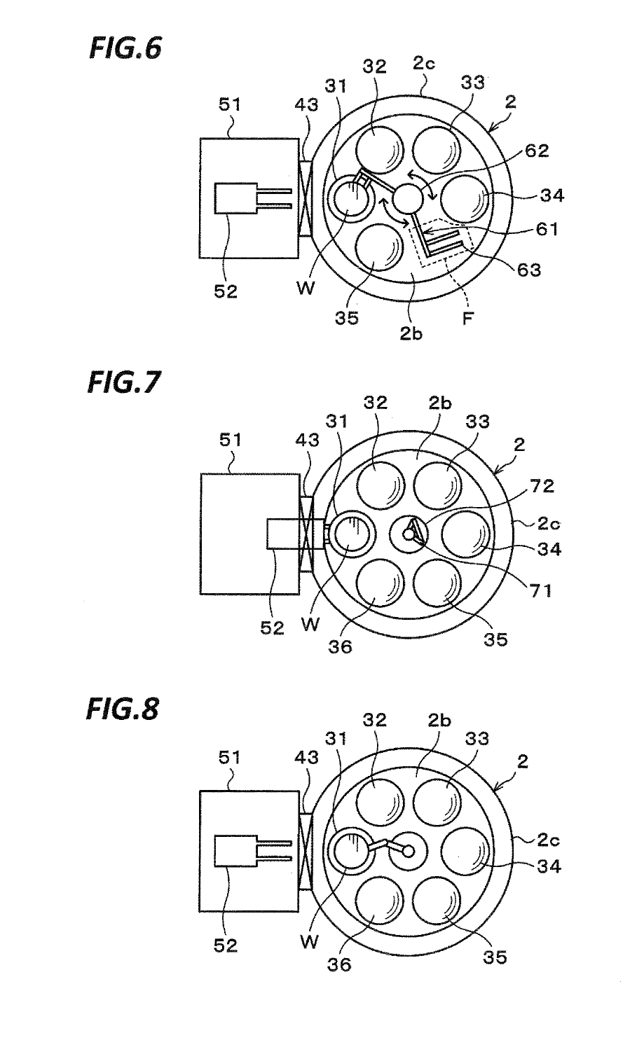

In order to solve this problem, for example, as illustrated in FIG. 6, it is proposed that a dedicated conveyance arm 61 be installed to deliver the wafer W to each of the substrate stages 31 to 35 within the processing container 2.

The conveyance arm 61 is configured to move up and down while rotating about the central axis 62 provided, for example, at the center of the bottom portion 2b of the processing container 2 and an arm portion 63 is accessible to each of the substrate stages 31 to 35. Using the substrate stage 31 in the vicinity of the gate valve to which the conveyance arm 52 within the load lock chamber 51 may deliver wafers W by a rectilinear movement as a relay point, the wafers W are delivered from the substrate stage 31 to other substrate stages 32 to 35 by the conveyance arm 61. By this, a conventional conveyance arm that moves on a straight line as in the related out is sufficient for the conveyance arm 52 in the load lock chamber 51.

Further, during the plasma processing, the processing may not be executed when the conveyance arm 61 is located above the wafer W on any of the substrate stages 31 to 35. Thus, the retraction space F may be set in advance within the processing container 2 when the substrate stages 31 to 35 are arranged, and the conveyance arm 61 may be retracted to the retraction space F during the processing.

However, in some kinds of plasma processings, it is expected that unexpected situations such as, for example, abnormal discharge during the processing even if the conveyance arm 61 was retracted to the retraction space F. In the case where such a situation is anticipated, a conveyance arm 71 as illustrated in FIG. 7 may be proposed.

The conveyance arm 71 is installed at the center of the substrate stages 31 to 36 that are annularly arranged on the bottom portion 2b in the processing container 2, and is located in a bottomed recess 72 having a circular shape in a plan view. The conveyance arm 71 is configured to be rotatable, extendible, and move up and down. When the conveyance arm 71 is not in use, the conveyance arm 71 is contracted and moved down to be received in the recess 72. When the conveyance arm 52 of the load lock chamber 51 conveys a wafer W into the processing container 2, the conveyance arm 71 is extended and moved to receive the wafer W as illustrated in FIG. 8. After receiving the wafer W, the conveyance arm 71 conveys the wafer W to a predetermined one of the substrate stages 31, 32, 33, 34, 35, 36.

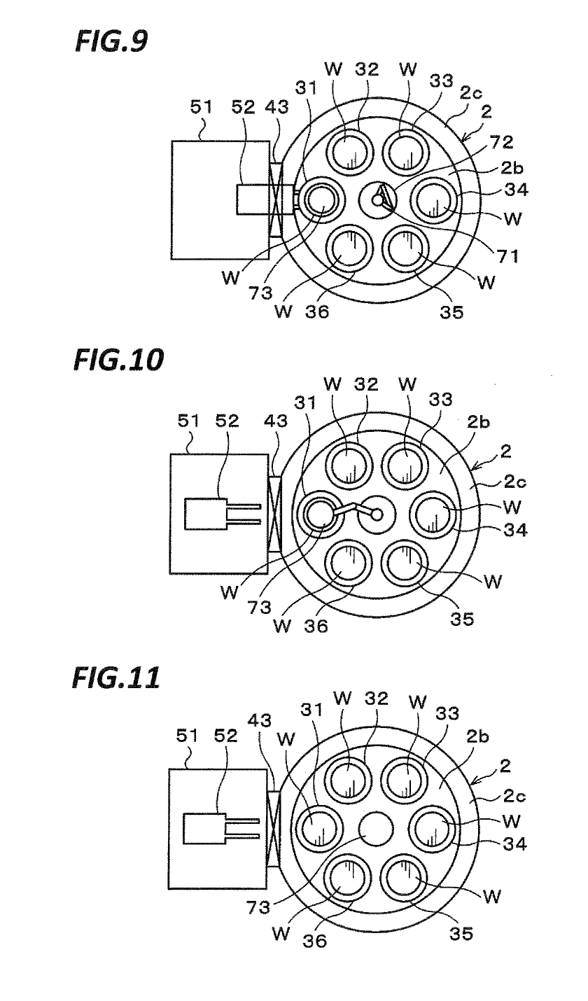

When such an operation is repeated and the conveyance of wafers W to all of the substrate stages 31 to 36 is completed, the conveyance arm 52 of the load lock chamber 51 conveys a cover 73 into the processing container 2, as illustrated in FIG. 9. The cover 73 has a size and a shape that may airtightly close the recess 72. As illustrated in FIG. 10, the conveyance arm 71 receives the cover 73 above the substrate stage 31. Then, the conveyance arm is contracted into the recess 72 and moved down while maintaining the cover 73. As illustrated in FIG. 11, the cover 73 airtightly closes the recess 72 from the upper side. Accordingly, the conveyance arm 71 is not exposed to the processing container 2, and thus, even if the plasma processing is performed, occurrence of the undesirable situation such as, for example, the abnormal discharge, can be suppressed.

A mechanism airtightly and completely accommodating the conveyance arm 71 may be installed in the processing container 2 during the processing without carrying the dedicated cover 73 into the processing container 2 from the outside. FIG. 13 illustrates such an example in which a cylindrical lower chamber 81 is provided at the center of the bottom portion 2b of the processing container 2, and the conveyance arm 71 is provided in the lower chamber 81. An upper chamber 82 configured to come in close contact with the lower chamber and move up and down is provided at the upper side within the processing container 2.

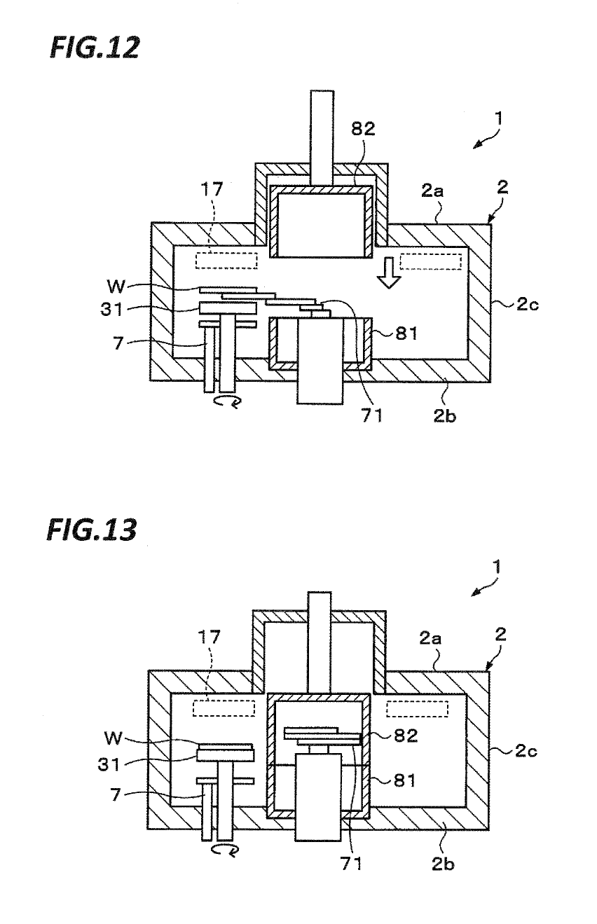

When a wafer W is delivered to each substrate stage (e.g., the substrate stage 31) or delivered between each substrate stage and the conveyance arm 52 within the load lock chamber 51, the upper chamber 82 is standing by at an upper position as illustrated in FIG. 12.

Thereafter, when the delivery of the wafer W to each substrate stage is completed and the plasma processing is initiated, the conveyance arm 71 is contracted to be accommodated in the lower chamber 81. Subsequently, as illustrated in FIG. 13, the upper chamber 82 moves down to come into close contact with the lower chamber 81, so that the conveyance arm 71 is airtightly accommodated within the upper and lower chambers 82 and 81. Thus, the conveyance arm 71 is not exposed within the processing container 2. Therefore, the above-described situations such as, for example, the abnormal discharge, do not occur even if the plasma processing is performed.

Further, in particular, in the case where the upper chamber 82 is installed within the processing container 2, it is difficult to employ the disc-shaped upper electrode 10 in that state. Thus, as illustrated in FIGS. 12 and 13, an upper electrode having the annular electrode body 17 illustrated in FIG. 4 may be employed.

The above-described exemplary embodiment exemplifies an etching apparatus for generating plasma using high frequency waves. However, without being limited to the etching apparatus, the present disclosure may be applied to a deposition apparatus or a sputtering apparatus. Furthermore, without being limited to flat plate type plasma in plasma source, the present disclosure may also be applied to a processing apparatus that generates plasma by other means, such as, for example, microwaves, or ICP plasma. In addition, the substrate may be a glass substrate, an organic EL substrate, or a substrate for a Flat-Panel Display (FPD) without being limited to the wafer.

The present disclosure is useful for an apparatus that performs a plasma processing, for example, on a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus that processes a substrate by converting a processing gas into plasma, the plasma processing apparatus comprising:
a processing container that airtightly accommodates the substrate therein;
a plurality of mounting tables provided at a lower side within the processing container, each of plurality of mounting tables being configured to place the substrate thereon; and
an upper electrode provided at an upper side within the processing container to face the plurality of mounting tables,
wherein the upper electrode is configured to be rotatable about a center of the upper electrode as a central axis within the processing container.

2. The plasma processing apparatus of claim 1, wherein each mounting table is configured to rotatable about a center of the mounting table as a central axis.

3. The plasma processing apparatus of claim 1, wherein the upper electrode has a plurality of radially zone-divided electrode bodies which is supplied with a high frequency wave.

4. The plasma processing apparatus of claim 1, wherein the upper electrode has an annular electrode body which is supplied with a high frequency wave.

5. The plasma processing apparatus of claim 1, wherein the upper electrode has a configuration in which a plurality of annular electrode bodies supplied with a high frequency wave are arranged concentrically.

6. The plasma processing apparatus of claim 5, wherein the high frequency wave supplied to each electrode body is individually subjected to an output control.

7. The plasma processing apparatus of claim 1, further comprising:
a conveyance arm configured to convey the substrate onto each of the plurality of mounting tables is installed within the processing container.

8. The plasma processing apparatus of claim 7, wherein the processing container includes a retraction space formed therein to allow the conveyance arm to be retracted without interfering with the plurality of mounting tables.

9. The apparatus of claim 7, wherein the processing container includes an accommodating portion formed therein, the accommodating portion being configured to airtightly accommodate the conveyance arm therein.

10. The apparatus of claim 9, wherein the accommodating portion includes a recess configured to accommodate the conveyance arm therein and a cover configured to airtightly close the recess.

11. The apparatus of claim 9, wherein the accommodating portion includes a lower chamber and an upper chamber configured to come into close contact with the lower chamber and move up and down.
